(19) United States
(12) Patent Application Publication
(10) Pub. No.: US 2019/0025694 A1
(43) Pub. Date: Jan. 24, 2019

(54) HIGH RESOLUTION PHOTOMASK OR RETICLE AND ITS METHOD OF FABRICATION

(71) Applicant: Intel Corporation, Santa Clara, CA (US)

(72) Inventor: Chang Ju CHOI, Fremont, CA (US)

(21) Appl. No.: 16/069,383

(22) PCT Filed: Mar. 31, 2016
(86) PCT No.: PCT/US2016/025269

§ 371 Date: Jul. 11, 2018

(51) Int. Cl. G03F 1/26

(52) U.S. Cl. CPC G03F 1/26

(57) ABSTRACT

Approaches for fabricating a lithographic mask are described. In an example, a lithographic mask for patterning semiconductor circuits includes a substrate. An in-die region is disposed on the substrate. The in-die region includes a patterned shifter material in direct contact with the substrate. The patterned shifter material includes features having sidewalls. A frame region is disposed on the substrate and surrounding the in-die region. The frame region includes an absorber layer in direct contact with the substrate.

### TECHNICAL FIELD

Embodiments of the invention are in the field of integrated circuit fabrication and, in particular, approaches for a fabricating a high resolution and reliable photomask or reticle.

### BACKGROUND

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory devices on a chip, lending to the fabrication of products with increased capacity. The drive for ever-more capacity, however, is not without issue. It has become increasingly significant to rely heavily on innovative photolithography techniques to meet the exceedingly tight space requirements imposed by scaling.

Photolithography is commonly used in a manufacturing process to form patterns in a layer of photoresist. In the photolithography process, a photoresist layer is deposited over an underlying layer that is to be etched. Typically, the underlying layer is a semiconductor layer, but may be any type of hardmask or dielectric material. The photoresist layer is then selectively exposed to radiation through a photomask or reticle. The photoresist is then developed and those portions of the photoresist that are exposed to the radiation are removed, in the case of “positive” photoresist.

The photomask or reticle used to pattern the wafer is placed within a photolithography exposure tool, commonly known as a “stepper.” In the stepper machine, the photomask or reticle is placed between a radiation source and a wafer. The photomask or reticle is typically formed from patterned chrome (absorber layer) placed on a quartz substrate. The radiation passes substantially unattenuated through the quartz sections of the photomask or reticle in locations where there is no chrome. In contrast, the radiation does not pass through the chrome portions of the mask. Because radiation incident on the mask either completely passes through the quartz sections or is completely blocked by the chrome sections, this type of mask is referred to as a binary mask. After the radiation selectively passes through the mask, the pattern on the mask is transferred into the photoresist by projecting an image of the mask into the photoresist through a series of lenses.

As features on the photomask or reticle become closer and closer together, diffraction effects begin to take effect when the size of the features on the mask are comparable to the wavelength of the light source. Diffraction blurs the image projected onto the photoresist, resulting in poor resolution.

One state of the art method of preventing diffraction patterns from interfering with the desired patterning of the photoresist is to cover selected openings in the photomask or reticle with a transparent layer known as a shifter. The shifter shifts one of the sets of exposing rays out of phase with another adjacent set, which nullifies the interference pattern from diffraction. This approach is referred to as a phase shift mask (PSM) approach. Nevertheless, alternative mask fabrication schemes that reduce defects and increase throughput in mask production are important focus areas of lithography process development.

### BRIEF DESCRIPTION OF THE DRAWINGS

FIG. 1 illustrates a cross sectional view of a lithography mask structure, in accordance with an embodiment of the present invention.

FIGS. 2A-2E illustrate cross sectional views representing various operations in a method of fabricating a photomask, in accordance with embodiments of the present invention, wherein:

FIG. 2A illustrates a resist pattern formed on a shifter layer disposed on a substrate;

FIG. 2B illustrates the structure of FIG. 2A following an etch process used to transfer the resist pattern into the shifter layer to form a patterned shifter layer, followed by resist removal;

FIG. 2C illustrates the structure of FIG. 2B following formation of an absorber layer on the patterned shifter layer and on the substrate;

FIG. 2D illustrates the structure of FIG. 2C following formation of a resist pattern on an absorber layer; and

FIG. 2E illustrates the structure of FIG. 2D following an etch process used to form patterned absorber layer in some regions while exposing previously patterned shifter layer in other regions, followed by resist removal.

FIGS. 3A-3E illustrate cross sectional views representing various operations in a method of fabricating a photomask, in accordance with embodiments of the present invention, wherein:

FIG. 3A illustrates a resist pattern formed on a dual stack including a hardmask above a shifter layer formed on a substrate;

FIG. 3B illustrates the structure of FIG. 3A following (i) an etch process used to transfer the resist pattern into the hardmask layer and (ii) resist removal;

FIG. 3C illustrates the structure of FIG. 3B following (i) an etch process used to transfer the hardmask pattern into the shifter layer to form a patterned shifter layer and (ii) hardmask layer removal;

FIG. 3D illustrates the structure of FIG. 3C following formation of an absorber layer on the patterned shifter layer and on the substrate;

FIG. 3E illustrates the structure of FIG. 3D following formation of a resist pattern on an absorber layer; and

FIG. 3F illustrates the structure of FIG. 3E following (i) an etch process used to pattern the absorber layer in some regions and to expose the previously patterned shifter layer in other regions and (ii) resist removal.

FIGS. 4A-4C illustrate cross sectional views representing various embodiments of the present invention, wherein:

FIG. 4A illustrates the structure of FIG. 2E, wherein etching an absorber layer leaves sidewall spacers of absorber material adjacent sidewalls of features of shifter layer;

FIG. 4B illustrates a magnified view of a portion of the die and die-frame interface region of FIG. 4A, wherein sidewall spacers of absorber material is formed adjacent to sidewalls of patterned shifter features; and

FIG. 4C illustrates a cross-sectional view of a recess formed in the substrate as a result of spacer removal from FIG. 4B.

FIGS. 5A-5C illustrate cross sectional views representing various operations in a method of fabricating a photomask, in accordance with an embodiment of the present invention, wherein:

FIG. 5A illustrates the structure of FIG. 2B following formation of an absorber layer on the patterned shifter layer and on the substrate, wherein the uppermost surface of the shifter on an in-die region is coplanar with the uppermost surface of the shifter in a frame region;

FIG. 5B illustrates the structure of FIG. 5A following formation of a resist pattern on an absorber layer; and

FIG. 5C illustrates the structure of FIG. 5B following (i) an etch process used to pattern absorber layer in some regions and to expose previously patterned shifter layer in other regions and (ii) resist removal.

FIG. 6 illustrates a cross-sectional view of a conventional photomask.

FIG. 7 illustrates a schematic of a transistor and associated memory element, each of which may be fabricated using a photomask or reticle, in accordance with an embodiment of the present invention.

FIG. 8 illustrates a block diagram of an electronic system, in accordance with an embodiment of the present invention.

FIG. 9 illustrates a computing device in accordance with one embodiment of the invention.

FIG. 10 illustrates an interposer that includes one or more embodiments of the invention.

### DESCRIPTION OF THE EMBODIMENTS

Approaches for fabricating a lithographic mask are described. In the following description, numerous specific details are set forth, such as novel structural schemes and detailed fabrication methods in order to provide a thorough understanding of embodiments of the present invention. It will be apparent to one skilled in the art that embodiments of the present invention may be practiced without these specific details. In other instances, well-known features, such as details of phase shift mask operation, are not described in detail in order to not unnecessarily obscure embodiments of the present invention. Furthermore, it is to be understood that the various embodiments shown in the Figures are illustrative representations and are not necessarily drawn to scale.

One or more embodiments of the present invention are directed to methods for fabricating lithographic masks and the resulting lithographic masks.

To provide context, the requirement to meet aggressive device scaling goals set forth by the semiconductor industry harbors on the ability of lithographic masks to pattern smaller features with high fidelity. However, approaches to pattern smaller and smaller features present formidable challenges for mask fabrication. In this regard, lithographic masks widely in use today rely on the concept of phase shift mask (PSM) technology to pattern features. However, reducing defects while creating smaller and smaller patterns remains one of the biggest obstacles in mask fabrication. Use of the phase shift mask may have several disadvantages. First, the design of a phase shift mask is a relatively complicated procedure that requires significant resources. Second, because of the nature of a phase shift mask, it is difficult to check whether or not defects are present in the phase shift mask. Such defects in phase shift masks arise out of the current integration schemes employed to produce the mask itself. Conventional phase shift masks adopt a cumbersome and somewhat defect prone approach to pattern thick light absorbing materials and then transfer the pattern to a secondary layer that aids in the phase shifting. To complicate matters, the absorber layer is subjected to plasma etch twice and, consequently, unwanted effects of plasma etch such as loading effects, reactive ion etch lag, charging and reproducible effects leads to defects in mask production.

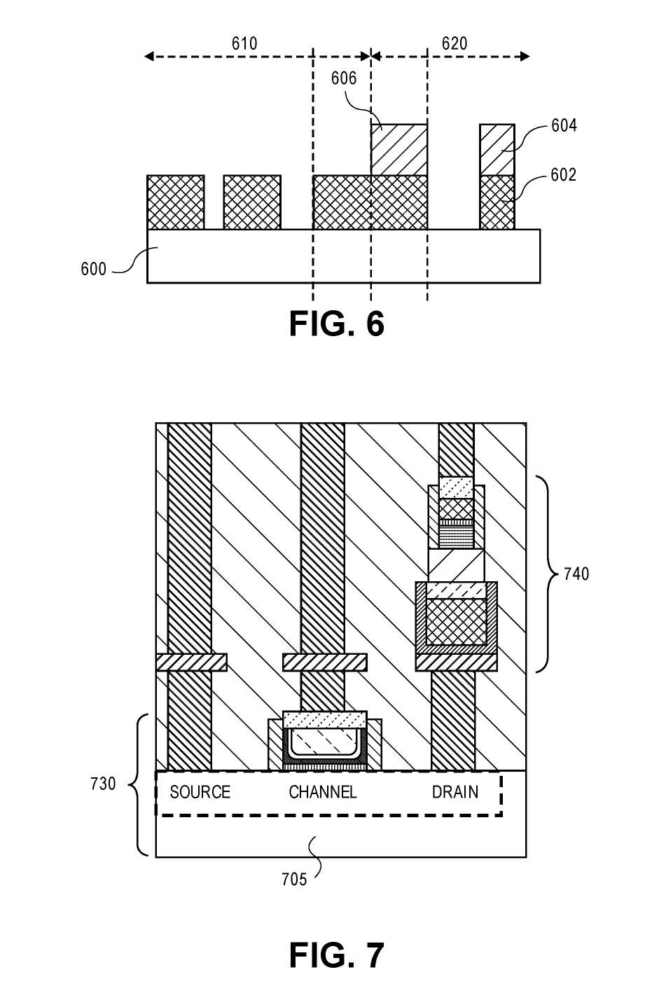

Conventional techniques for fabrication of a phase shift mask (PSM) employ patterning of an etch un-friendly absorber layer to define finer features in a shifter layer disposed directly below the absorber layer, as is illustrated in FIG. 6. FIG. 6 also depicts a shifter layer patterned into two regions. A die region 610 includes a patterned shifter layer 602 disposed on a substrate 600 with critical features having dimensions ranging from 20-1000 nm. A frame region 620 directly surrounds the die region and includes features that range from 100-2000 nm, wherein the features are a dual layer stack having an absorber layer 604 directly on a shifter layer 602. However, the patterning of a shifter layer using a patterned absorber layer directly there above as a mask can lead to process errors and production issues during mask fabrication.

Hence, innovation in materials and novel integration techniques to fabricate defect free lithographic masks remains a high priority to enable device scaling. Accordingly, in order to exploit the full benefits of a phase shift mask technology, a novel integration scheme that employs (i) patterning a shifter layer with high fidelity and (ii) patterning an absorber only once and during the final stages of fabrication may be needed. Additionally, such a fabrication scheme may also offer other advantages such as flexibility in material choices, decreased substrate damage during fabrication, and increased throughput in mask fabrication.

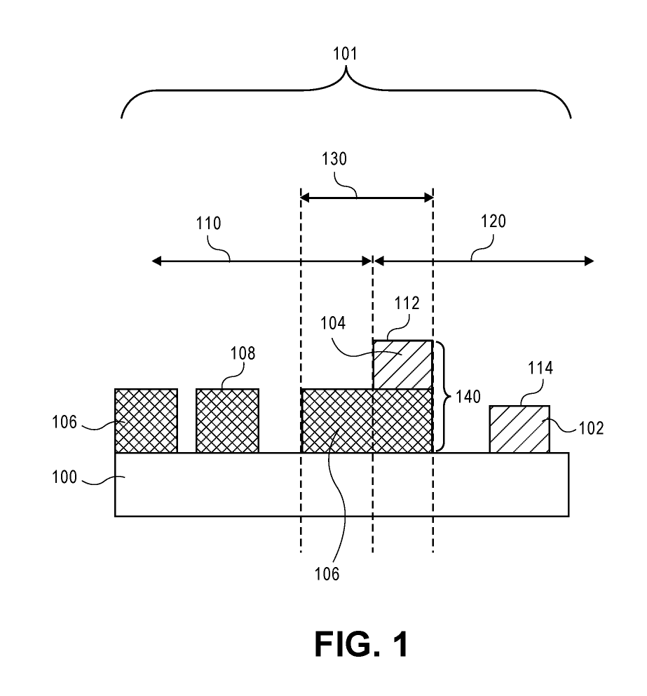

FIG. 1 illustrates a cross sectional view of a lithography mask structure 101 in accordance with an embodiment of the present invention. The lithography mask 101 includes an in-die region 110, a frame region 120 and a die-frame interface region 130. The die-frame interface region 130 includes adjacent portions of the in-die region 110 and the frame region 120. The in-die region 110 includes a patterned shifter layer 106 disposed directly on a substrate 100, wherein the patterned shifter layer has features that have sidewalls. The frame region 120 surrounds the in-die region 110 and includes a patterned absorber layer 102 disposed directly on the substrate 100.

The die-frame interface region 130, disposed on substrate 100, includes a dual layer stack 140. The dual layer stack 140 includes an upper layer 104, disposed on the lower patterned shifter layer 106. The upper layer 104 of the dual layer stack 140 is composed of a same material as the patterned absorber layer 102 of the frame region 120.

In an embodiment, an uppermost surface 108 of the features of the patterned shifter layer 106 have a height that is different than an uppermost surface 112 of features of the die-frame interface region and different than an uppermost surface 114 of the features in the frame region. Furthermore, in an embodiment the height of the uppermost surface 112 of the features of the die-frame interface region is different than the height of the uppermost surface 114 of the features of the frame region. Typical thickness of the phase shifter layer 106 ranges from 40-100 nm, while a typical thickness of the absorber layer ranges from 30-100 nm. In an embodiment, the thickness of the absorber layer 102 in the frame region 120 is 50 nm, the combined thickness of the absorber layer 104 which is disposed on the shifter layer 106 in the die-frame interface region 130 is 120 nm and the thickness of the absorber in the frame region is 70 nm. In an embodiment, the substrate 100 is quartz, the patterned shifter layer includes a material such as but not limited to molybdenum-silicide, molybdenum-silicon oxynitride, molybdenum-silicon nitride, silicon oxynitride, or silicon nitride, and the absorber material is chrome.

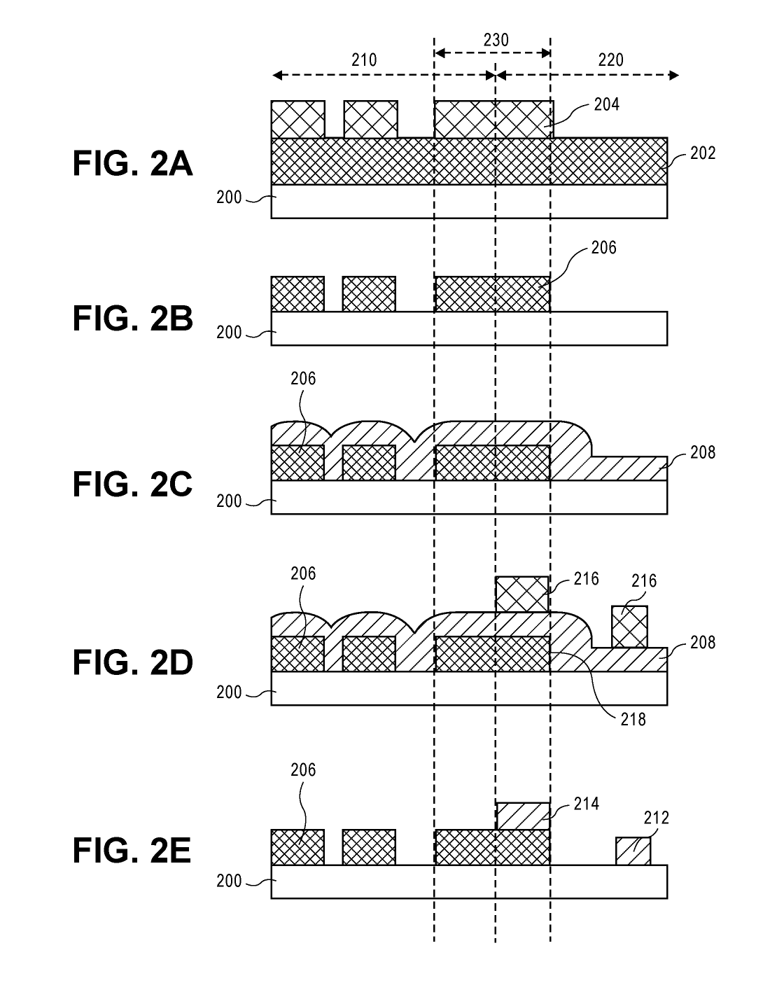

FIGS. 2A-2E illustrate cross sectional views representing various operations in a method of fabricating a lithographic mask 101, in accordance with an embodiment of the present invention. The fabrication process outlined in FIGS. 2A-2E illustrates a conventional two phase process marked by two distinct lithography and etch process operations. The first phase of the fabrication process defines features in the die region 110, wherein the features include high resolution lithographically patterned devices with width ranging in the 20-1000 nm range. The second phase of the fabrication process defines features in the frame region 120, wherein the features include relatively low resolution lithography patterns typically not associated with circuits or devices, but may contain other process specific relevant structures such as alignment marks and metrology structures. In an embodiment, such low resolution features have widths range from 100-2000 nm.

FIG. 2A illustrates a resist pattern 204 formed on a shifter layer 202 disposed on a substrate 200. The shifter layer 202 is a material known in the art as a phase shifter. The patterned shifter layer may include a material such as but not limited to molybdenum-silicide or silicon nitride. A thickness for the shifter layer 202 typically ranges from 50-80 nm. The requirement to control interference patterns produced by transmission of light through a patterned shifter layer, during operation of the lithographic mask 101 may dictate the thickness of this layer.

Referring again to FIG. 2A, a photoresist material is formed over the shifter layer 202 and patterned to form a patterned photoresist layer 204. The patterned photoresist layer 204 defines two distinct regions on the substrate 200 (i) an in-die region and (ii) a frame region. Photoresist layer 204 may include other patterning materials such as anti-reflective coatings (ARC) and gap-fill and planarizing materials in addition to or in place of a photoresist material. Photoresist layer 204 is formed to a thickness sufficient to retain its profile while patterning shifter layer 202 but yet is not formed too thick to prevent lithographic patterning into the smallest dimensions (i.e., critical dimensions) possible with photolithography system and process used. Given the requirement to define 20-100 nm, in an embodiment such high resolution patterning is typically carried out using an electron beam lithography technique.

FIG. 2B illustrates a patterned shifter layer 206 from shifter layer 202 with a pattern formed therein. An anisotropic plasma etch process may be used to transfer the resist pattern into the shifter layer. The etching may be followed by a resist strip and cleans to remove etch residue. In an embodiment, the etch process removes all of the material in the shifter layer 202 directly in contact with the substrate that is not covered by photoresist. That is, the etch exposes and stops on the substrate 200.

Referring to again to FIG. 2B, an etch selectivity of greater than 4 to 1 between photoresist material and shifter material may be desirable. In other words, the rate of removal of shifter material 202 should be more than four times the rate of erosion of the photoresist to create a patterned shifter layer 206. Chemical etchants utilized in the plasma etch process will depend on the material composition of the shifter layer 202 being etched. In other embodiments where the shifter layer is a MoSi or SiN, etchants may include but not be limited to CHₓF_{y}, SF₆, O₂, Ar, N₂ and CF₄. Sidewalls of features of the patterned shifter layer 206 can be tailored in one or more embodiments to vary from 80-90 degrees from the substrate 202 surface depending on the type of etch conditions employed as is well known in the art. Additionally, etch selectivity while patterning shifter layer 202 to underlying substrate 200 is also important for defining interference characteristics of the lithographic mask 101. Since the relative phase difference between light transmitted through a combination of patterned shifter layer 206 and the substrate 200 and light transmitted through just the substrate 200 will govern patterning fidelity of the lithographic mask 101, it is important to maintain a uniform thickness of the substrate at various locations in the die region 210.

Referring again to FIG. 2B, after forming the patterned shifter layer 206, the photoresist layer 204 is removed. In an embodiment, following a plasma based photoresist removal process or plasma ashing, the upper most surface of the patterned shifter layer 206 is exposed. The ash process, which may include of a gas containing O₂, H₂/N₂, removes photoresist 204 selectively to the shifter layer 202 and the exposed substrate 200. A wet chemical cleaning process or wet cleans may subsequently be utilized to remove any residue and defects generated during an anisotropic plasma etch and ash process. In one embodiment, a mixture containing buffered hydrofluoric acid, water and peroxide is used to remove residue so as to minimize increase in features of the patterned shifter layer 206.

FIG. 2C illustrates the structure of FIG. 2B following formation of an absorber layer on the patterned shifter layer 206 and on the substrate 200. In an embodiment, in accordance with the present invention, the profile of the absorber layer 208 is conformal to the patterned shifter material 206. That is, the uppermost surface of absorber layer 208 formed on the shifter layer 206 is at a higher level than the uppermost surface of the absorber layer 208 formed on the substrate 200 exposed by the patterned shifter layer 206. The thickness of the absorber layer ranges from 30-100 nm. The purpose of the absorber layer is, as the name suggests, to provide light opacity to frame region 220 in the lithographic mask in a subsequent lithography operation. In an embodiment where the process operation adopts 193 nm lithography wavelength for patterning, the absorber layer 208 may include a material such as but not limited to chrome, tantalum and titanium nitride. In an embodiment where such an absorber layer 208 is implemented for patterning with extreme ultra-violet lithography, a tantalum nitride material is used.

FIG. 2D illustrates the structure of FIG. 2C following a second lithography operation. The second lithography operation patterns a resist material into a patterned resist layer 216 on the absorber layer 208 and defines features in the frame region 220. Photoresist layer 216 is formed to a thickness sufficient to retain its profile while patterning absorber layer 208. It is to be appreciated that given the requirement to define features larger than 100 nm in the frame region 220, thickness requirements on photoresist layer 216 may be relaxed compared to the thickness of the photoresist layer 204 used to pattern finer features in the die region 210. As is known in the art, patterning of photoresist to define features greater than 100 nm is typically carried out using a flood exposure technique. It is to be further appreciated that that the uppermost surface of the absorber layer over which the second resist layer 216 is formed is not a topographically flat substrate. Hence, additional fine tuning of the thickness of the absorber layer 208 as well as fine tuning lithographic parameters such as, but not limited to, resist thickness, depth of focus and patterning dose may be required to form features in the frame area to conform to specifications of the present invention. It is to be appreciated that in further embodiments of the present invention, a misalignment between resist layer 216 and a vertical sidewall 218 of the patterned shifter layer 206 may lead to additional masking effects in the frame area. In one such embodiment, the enhancement of the feature size due to masking effects may be compensated for during the lithographic patterning process defining shifter layer 202.

FIG. 2E illustrates the structure of a lithographic mask 201 with features defining an in-die region 210 and a frame region 220. An anisotropic plasma etch process may be used to form a patterned absorber layer 212 on the substrate in the frame region 220 and a patterned absorber layer 214 in the die-frame interface region 230, while exposing a previously patterned shifter layer 206 in the die region 210. In one embodiment, a resist strip and wet cleans after the plasma etch process is carried out to remove remaining photo resist and clean etch residue.

In an embodiment, a plasma etch process is used to pattern a chrome absorber layer and utilizes etchants including Cl₂, O₂, N₂ and Ar. In an embodiment, the absorber layer is removed everywhere from the regions other than those covered by photoresist. Subsequently, in one such embodiment, due to the conformal nature of the absorber layer 208, two different material surfaces are exposed simultaneously while etching absorber layer 208: (i) the uppermost surface of the shifter layer 206 in the die region 210 and (ii) the uppermost surface of the substrate 200 in the frame region as well as the uppermost surface of the substrate 200 in the patterned features of the patterned shifter layer 206 in the die region 210. Given that interference and diffraction effects drive the performance of a lithographic mask, thickness and edge related defects are important patterned shifter layer features required to be controlled. In an embodiment, the patterning of the absorber layer 208 is performed with high selectivity to the uppermost surface and the sidewalls of features of the patterned shifter layer 206. In one embodiment, patterning a chrome absorber layer 208 selectively to a MoSi shifter layer 206 involves use of multi-faceted recipes that control the flow of O₂ and Ar in the Cl₂ mixture to create an energetically favorable chrome etch, but a significantly gentler chrome over etch to preserve features in the patterned shifter layer 206. Selectivity to underlying substrate 200 may be equally important. The regions of the substrate 200 not covered by patterned shifter layer 206 and patterned absorber layer 212 may be exposed to an onslaught of the bombarding plasma ions for a second time. In this regard, in an embodiment, the last 2-3 nm of a chrome containing absorber layer may be removed by wet etch in a mixture including acetic acid, water and ammonium cerium nitrate.

While patterning a shifter layer using a resist mask may offer process advantages over patterning a shifter using a chrome mask, an alternative embodiment may include use of a hardmask to pattern a shifter layer. Such an embodiment may offer benefits for further improving line edge roughness as a hardmask, typically, can withstand the erosive effects of plasma ion bombardment to a greater extent than a thin patterned photoresist. In light of aggressive scaling of feature sizes to accommodate the onslaught of Moore's law, an implementation of a hardmask serves to decrease the overall percentage of line edge roughness compared to the critical dimension of a given feature.

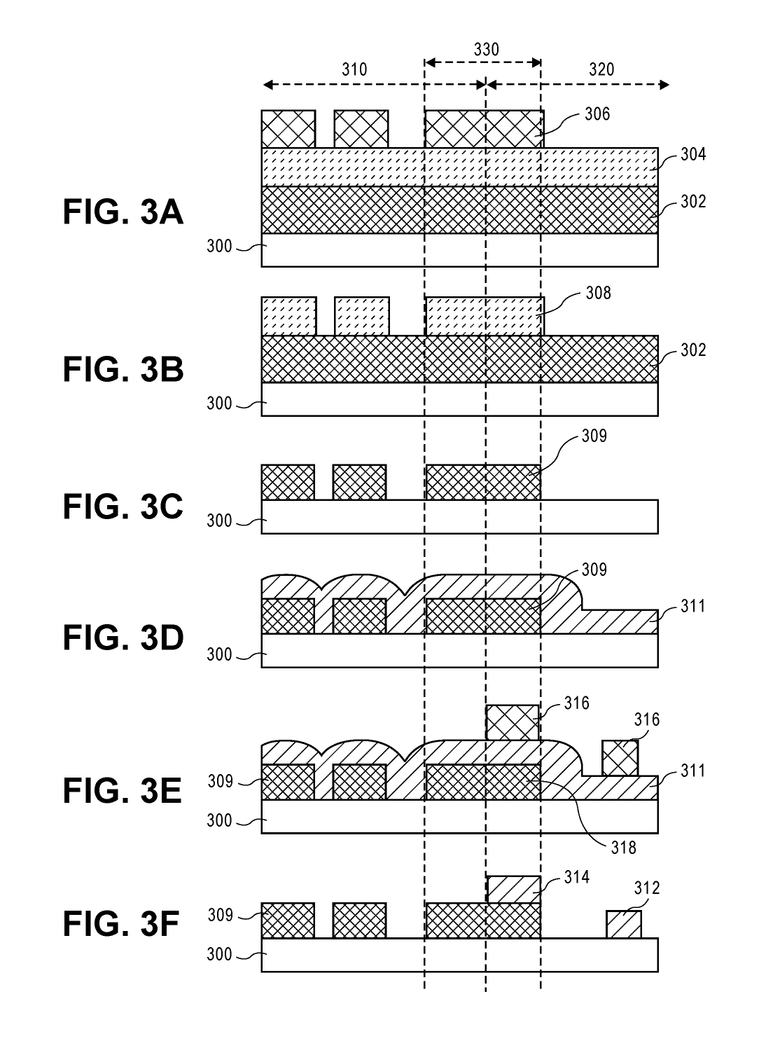

In this regard, FIGS. 3A-3F illustrate cross sectional views representing various operations in a method of fabricating a lithographic mask 101, where patterning of a shifter layer is preceded by a patterning of a hardmask layer.

FIG. 3A illustrates a resist pattern 306 formed on a dual layer stack including a hardmask 304 above a shifter layer 302 formed on a substrate 300. The shifter layer 302 may include a material such as but not limited to molybdenum-silicide, molybdenum silicon nitride, or silicon nitride. The hardmask layer 304 may include a material such as but not limited to chrome, silicon dioxide or silicon nitride. Thickness of the hardmask layer 304 may range from 3 nm-50 nm and will depend on the choice of hardmask material, process flow and the smallest dimension of the features to be patterned.

Referring again to FIG. 3A, a photoresist material is formed on the hardmask layer 304 and patterned to form a patterned resist layer 306. The patterned resist layer 306 defines two distinct regions on the wafer (i) an in-die region 310 and (ii) frame region 320. Patterned photoresist layer 306 may include other patterning materials such as anti-reflective coatings (ARC) and gap-fill and planarizing materials in addition to or in place of a photoresist material. In an embodiment, patterned photoresist layer 306 is formed to a thickness sufficient to retain its profile while patterning hardmask layer 304, but yet is not formed too thick to prevent lithographic patterning into the smallest dimensions (i.e., critical dimensions) possible with photolithography system and process used. For a given requirement to define 20-100 nm, in an embodiment such high resolution patterning is typically carried out using an electron beam lithography technique.

FIG. 3B illustrates the structure of FIG. 3A following patterning of the hardmask layer 304 to form a patterned hardmask layer 308. In an embodiment, an anisotropic plasma etch process is used to transfer the resist pattern into the hardmask layer 304, and a resist strip and cleans used to remove etch residue. In an embodiment, patterning of a silicon nitride or a silicon dioxide hardmask can be carried out using gases containing fluorine in combined to Ar, O₂ and N₂ with excellent selectivity to photoresist. However, the requirement to be selective to the shifter layer 302 may be somewhat relaxed. In an embodiment, the process of removing photoresist layer 306 and cleaning the substrate follows etching hardmask layer 304 but precedes etching shifter layer 302. However, the photoresist may remain in place until the shifter layer 302 is patterned.

FIG. 3C illustrates the structure of FIG. 3B following patterning of the shifter layer 302 to provide a patterned shifter layer 309. In an embodiment, the process follows an anisotropic plasma etch process used to transfer the pattern of the patterned hardmask 308 into shifter layer 302. In an embodiment, the etch process removes all of the material in the shifter layer 302 directly in contact with the substrate that is not covered by the patterned hardmask layer 308. That is, the etch exposes and stops on the substrate 300. The presence of a hardmask to pattern shifter layer 302 may also result in a vertical profile of the features of the patterned shifter layer 309 due to a finer control of hardmask erosion.

Following formation of the patterned shifter layer 309, in an embodiment, patterned hardmask layer 308 is removed selectively to the shifter layer 302 and substrate 300 using plasma etch or wet etch methods well known in the art. In another embodiment, if the patterned hardmask layer 308 is an ultra-thin 3 nm layer of chrome, the hardmask layer may remain on the patterned shifter layer 309.

FIG. 3D illustrates the structure of FIG. 3C following formation of an absorber layer 311 on the patterned shifter layer 309 and on the substrate. In an embodiment, in accordance with the present invention, the profile of the absorber layer 311 is conformal to the patterned shifter layer 309. That is, the uppermost surface of absorber layer 311 formed on the patterned shifter layer 309 is at a higher level than the uppermost surface of the absorber layer 31 formed on regions of the substrate 300 exposed by the patterned shifter layer 309. In an embodiment, the thickness of the absorber layer 311 ranges from 30-100 nm. In one embodiment, the purpose of the absorber layer 311 is, as the name suggests, to provide light opacity to frame region 320 in the lithographic mask in a subsequent lithography operation. In an embodiment where the process operation adopts 193 nm lithography wavelength for patterning, the absorber layer 311 may include a material such as but not limited to chrome, tantalum and titanium nitride. In an embodiment where such an absorber layer 311 is implemented for patterning with extreme ultra-violet lithography, a tantalum nitride material is used.

FIG. 3E illustrates the structure of FIG. 3D following a second lithography operation. The process operation provides a patterned resist layer 316 on the absorber layer 311 and defines features in the frame region 320. In an embodiment, patterned photoresist layer 316 is formed to a thickness sufficient to retain its profile while patterning absorber layer 311. In an embodiment, it is to be appreciated that given a requirement to define features larger than 100 nm in the frame region 320, the thickness requirements on patterned photoresist layer 316 may be further relaxed compared to the thickness of the photoresist layer 306 used to pattern finer features in the die region 310.

As is known in the art, patterning of photoresist to define features greater than 100 nm is typically carried out using a flood exposure technique. It is to be further appreciated that that the uppermost surface of the absorber layer over which the second resist layer 316 is formed is not a topographically flat substrate. Hence, additional fine tuning of the thickness of the absorber layer 311 as well as fine tuning lithographic parameters such as, but not limited to, resist thickness, depth of focus and patterning dose may be required to form features in the frame area to conform to specifications of the present invention. It is to be appreciated that in further embodiments of the present invention, misalignment between resist layer 316 and a vertical sidewall 318 of the patterned shifter layer 309 may lead to additional masking effects in the frame area. In one such embodiment, the enhancement of the feature size due to masking effects may be compensated for during the patterning of the shifter layer.

FIG. 3F illustrates the structure of a lithographic mask 301 with features defining an in-die region 310 and a frame region 320. In an embodiment, an anisotropic plasma etch process is used to form a patterned absorber layer 312 on the substrate in the frame region 320, and a patterned absorber layer 314 in the die-frame interface region 330, and exposing a previously patterned shifter layer 309 in the die region 310. In one embodiment, a resist strip and wet cleans after the plasma etch process is carried out to remove remaining photo resist and clean etch residue.

In an embodiment, a plasma etch process is used to pattern a chrome absorber layer and utilizes etchants including Cl₂, O₂, N₂ and Ar. In an embodiment, the absorber layer is removed everywhere from the regions other than those covered by photoresist. Subsequently, in one such embodiment, due to the conformal nature of the absorber layer 311, two different material surfaces are exposed simultaneously while etching absorber layer 208: (i) the uppermost surface of the patterned shifter layer 309 in the die region 310 and (ii) the uppermost surface of the substrate 300 in the frame region as well as the uppermost surface of the substrate 300 in the patterned features of the patterned shifter layer 309 in the die region 310. Given that interference and diffraction effects drive the performance of a lithographic mask, thickness and edge related defects are important patterned shifter layer features required to be controlled. In an embodiment, the patterning of the absorber layer 311 is performed with high selectivity to the uppermost surface and the sidewalls of features of the patterned shifter layer 309. In one embodiment, patterning a chrome absorber layer 311 selectively to a MoSi shifter layer 309 involves use of multi-faceted recipes that control the flow of O₂ and Ar in the Cl₂ mixture to create an energetically favorable chrome etch, but a significantly gentler chrome over etch to preserve features in the patterned shifter layer 309. Selectivity to underlying substrate 300 may be equally important. The regions of the substrate 300 not covered by patterned shifter layer 309 and patterned absorber layer 312 may be exposed to an onslaught of the bombarding plasma ions for a second time. In this regard, in an embodiment, the last 2-3 nm of a chrome containing absorber layer may be removed by wet etch in a mixture including acetic acid, water and ammonium cerium nitrate.

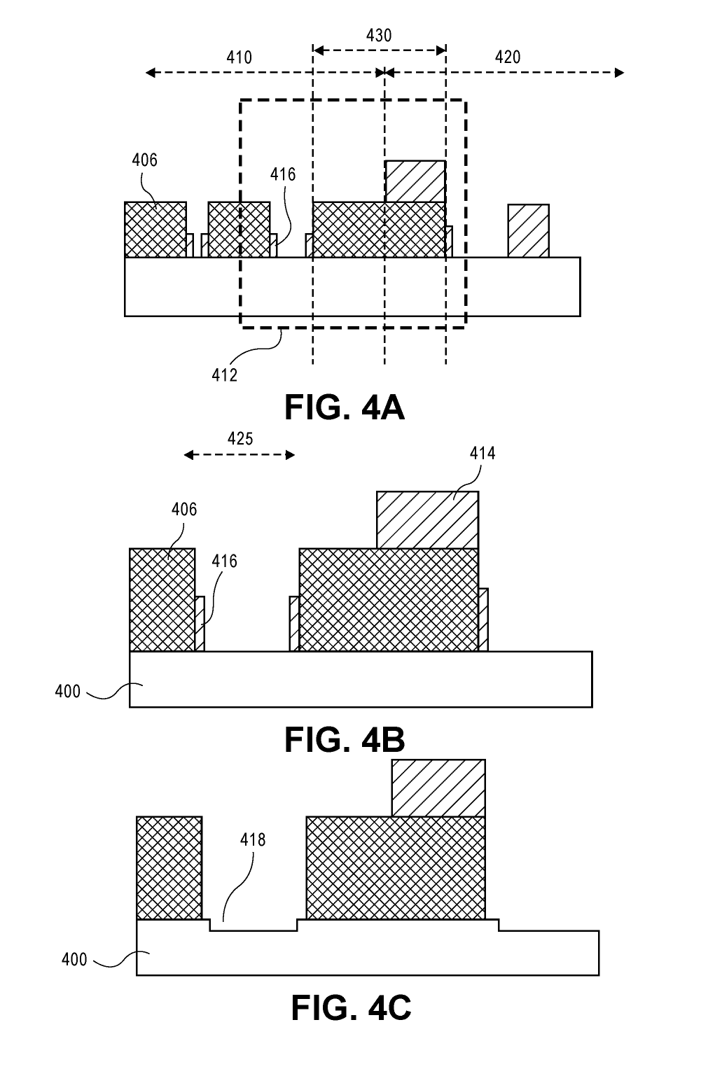

In contrast to the structure depicted in FIG. 2E and FIG. 3F, etching of conformal films adjacent to a sidewall may also lead to formation of spacer on the sidewall. FIGS. 4A-4C illustrates cross sectional views representing sidewall spacer 416 of absorber material on sidewalls of features of shifter layer 406 and their associated removal, in accordance with an embodiment of the present invention.

Referring to FIG. 4A, spacers consisting of absorber material 416 typically form when a conformal absorber layer 416 is anisotropically etched. A portion 412 of the lithographic mask from the die region 410 and die-frame interface region 430 is highlighted and will be presented below.

FIG. 4B illustrates a magnified view of a portion 412 from FIG. 4A, wherein sidewall spacers 416 made from an absorber layer are formed adjacent to sidewalls of patterned shifter features 406. In an embodiment, the width of the feature in the patterned shifter layer 425 will dictate to some extent the height of the sidewall spacer 416 formed, as a tightly packed space may exhibit features resembling gap fill rather than a spacer and may also exhibit a different response to a plasma etch. Hence, the sidewall spacer 416 located on the sidewall of the patterned shifter 406 in the frame region 420 may be taller than the spacer 416 inside the densely packed feature in the die region 410. Regardless of the height the sidewall spacer 416, which is composed of the same material as the absorber layer 416, the sidewall spacer 416 acts as an opaque light filter, and hence the name light absorber or just absorber. In this regard, for effective functionality as a lithographic mask and elimination of unwanted structures being formed, these spacers consisting of absorbing layer 416 may need to be removed. In an embodiment, spacer removal is most important for the die region where small device features are patterned.

While etching a layer of absorber layer 414 presents challenges, the removal of sidewall spacers 416 from the sidewalls of a patterned shifter layer 406 may present more formidable challenges. However, in one embodiment, the absorber layer is a chrome material and may be removed by a wet etch that is non-corrosive to the underlying substrate. In another embodiment, the absorber spacer 416 is removed via a plasma etch. In accordance with one such embodiment, FIG. 4C illustrates a small recess 418 formed in the substrate 400 as a result of the sidewall spacer 416 removal with a plasma etch process.

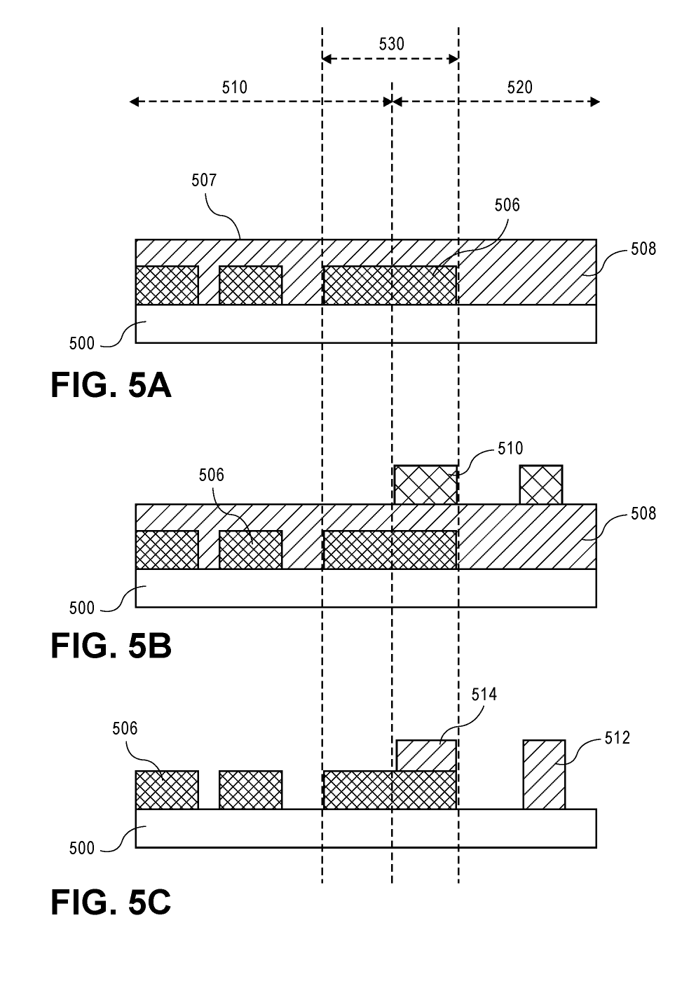

In another embodiment of the present invention, the concept of an idealized absorber layer is presented. FIGS. 5A-5C illustrate cross sectional views representing various operations in a method of fabricating a photomask from the starting point of FIG. 2B. FIG. 5A illustrates the structure of FIG. 2B following formation of an absorber layer 508 on the patterned shifter layer 506 and on the substrate 500, wherein the uppermost surface of the patterned shifter layer 506 on the in-die region 510 is coplanar with the uppermost surface of the patterned shifter layer 506 in the frame region 520. In one embodiment, such a coplanarity offers lithographic advantages as the absorber layer 508 is flat everywhere. In an embodiment, the absorber is planarized to remove undulation or topography as illustrated in FIG. 2C, and create a planar surface 507.

FIG. 5B illustrates the structure of FIG. 5A following formation of a resist pattern 510 on an absorber layer 508. The nature of the resist patterning has been described in connection with FIG. 2D. However, in this embodiment, the patterning fidelity of the resist layer 510 during a flood exposure to expose the frame region 520 may constitute an improvement over the resist patterning described in association with FIG. 2D.

FIG. 5C illustrates the structure of FIG. 5B following patterning of the absorber layer 508. In an embodiment, an anisotropic plasma etch process is used to pattern absorber layer 508 in the frame region 520 while exposing previously patterned shifter layer in the die region 510. In one embodiment, the etching is followed by a resist strip and wet cleans to remove etch residue. In an embodiment, the contrasting feature of this operation compared to FIG. 2E is that when the uppermost surface of the patterned shifter layer 506 is first exposed during the plasma etch process, the absorber layer 508 is coplanar everywhere, other than only in areas where it is covered by resist layer 510. Such a process technique may offer etch selectivity advantages as the etchants directed to removal of the absorber layer 508 rather than attacking the exposed uppermost surface of the patterned shifter layer 506. Upon further etching, the material of the absorber layer 508 is removed from filled areas in the features of the patterned shifter layer 506, resulting in a lithographic mask. It is to be appreciated that the absorber layer 512 in FIG. 5E is a true absorber in the frame region in contrast to the absorber 616 in the frame region 620 of FIG. 6 in the conventional lithography mask.

Lithographic mask 101 in connection with FIG. 1, has been described as an example of a phase change mask in an embodiment of the present invention. While there are innumerable usages of lithographic mask 101 in the semiconductor arena, one very important application is the ability to pattern different components of an integrated circuit, such as a transistors and/or memory elements. With the rising complexities of scaling along with those associated with creating three-dimensional transistors the number of lithography operations has increased many folds. A simple rendition of such a transistor is depicted in FIG. 7, in accordance with an embodiment of the embodiment of the present invention.

Referring to Figure, a transistor 730 is formed on a substrate 705. A memory element 740, such as a magnetic random access memory (MRAM) or dynamic random access memory (DRAM memory element), is coupled to the transistor 730.

In an embodiment, an underlying semiconductor substrate 705 represents a general workpiece object used to manufacture integrated circuits. The semiconductor substrate often includes a wafer or other piece of silicon or another semiconductor material. Suitable semiconductor substrates include, but are not limited to, single crystal silicon, polycrystalline silicon and silicon on insulator (SOI), as well as similar substrates formed of other semiconductor materials. The substrate may also include semiconductor materials, metals, dielectrics, dopants, and other materials commonly found in semiconductor substrates. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. Although a few examples of materials from which the substrate may be formed are described here, any material that may serve as a foundation upon which a semiconductor device may be built falls within the spirit and scope of the present invention.

In an embodiment, transistors associated with substrate 705 are metal-oxide-semiconductor field-effect transistors (MOSFET or simply MOS transistors), fabricated on the substrate 705. In various implementations of the invention, the MOS transistors may be planar transistors, nonplanar transistors, or a combination of both. Nonplanar transistors include FinFET transistors such as double-gate transistors and tri-gate transistors, and wrap-around or all-around gate transistors such as nanoribbon and nanowire transistors.

In an embodiment, each MOS transistor 730 of substrate 705 includes a gate stack formed of at least two layers, a gate dielectric layer and a gate electrode layer. The gate dielectric layer may include one layer or a stack of layers. The one or more layers may include silicon oxide, silicon dioxide (SiO₂) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used. In some implementations, a portion of the gate dielectric is a “U”-shaped structure that includes a bottom portion substantially parallel to the surface of the substrate and two sidewall portions that are substantially perpendicular to the top surface of the substrate.

The gate electrode layer of each MOS transistor of substrate 705 is formed on the gate dielectric layer and may consist of at least one P-type workfunction metal or N-type workfunction metal, depending on whether the transistor is to be a PMOS or an NMOS transistor. In some implementations, the gate electrode layer may consist of a stack of two or more metal layers, where one or more metal layers are workfunction metal layers and at least one metal layer is a conductive fill layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a workfunction that is between about 3.9 eV and about 4.2 eV.

In some implementations, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further implementations of the invention, the gate electrode may consist of a combination of U-shaped structures and planar, non-U-shaped structures. For example, the gate electrode may consist of one or more U-shaped metal layers formed atop one or more planar, non-U-shaped layers.

In some implementations of the invention, a pair of sidewall spacers may be formed on opposing sides of the gate stack that bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process operations. In an alternate implementation, a plurality of spacer pairs may be used, for instance, two pairs, three pairs, or four pairs of sidewall spacers may be formed on opposing sides of the gate stack.

As is well known in the art, source and drain regions are formed within the substrate adjacent to the gate stack of each MOS transistor. The source and drain regions are generally formed using either an implantation/diffusion process or an etching/deposition process. In the former process, dopants such as boron, aluminum, antimony, phosphorous, or arsenic may be ion-implanted into the substrate to form the source and drain regions. An annealing process that activates the dopants and causes them to diffuse further into the substrate typically follows the ion implantation process. In the latter process, the substrate may first be etched to form recesses at the locations of the source and drain regions. An epitaxial deposition process may then be carried out to fill the recesses with material that is used to fabricate the source and drain regions. In some implementations, the source and drain regions may be fabricated using a silicon alloy such as silicon germanium or silicon carbide. In some implementations the epitaxially deposited silicon alloy may be doped in situ with dopants such as boron, arsenic, or phosphorous. In further embodiments, the source and drain regions may be formed using one or more alternate semiconductor materials such as germanium or a group III-V material or alloy. And in further embodiments, one or more layers of metal and/or metal alloys may be used to form the source and drain regions.

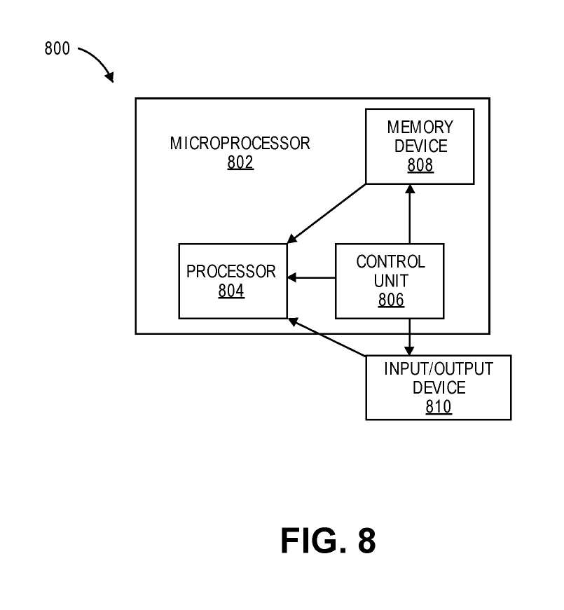

FIG. 8 illustrates a block diagram of an electronic system 800, in accordance with an embodiment of the present invention. The electronic system 800 can correspond to, for example, a portable system, a computer system, a process control system, or any other system that utilizes a processor and an associated memory. The electronic system 800 may include a microprocessor 802 (having a processor 804 and control unit 806), a memory device 808, and an input/output device 810 (it is to be understood that the electronic system 800 may have a plurality of processors, control units, memory device units and/or input/output devices in various embodiments). In one embodiment, the electronic system 800 has a set of instructions that define operations which are to be performed on data by the processor 804, as well as, other transactions between the processor 804, the memory device 808, and the input/output device 810. The control unit 806 coordinates the operations of the processor 804, the memory device 808 and the input/output device 810 by cycling through a set of operations that cause instructions to be retrieved from the memory device 808 and executed. The memory device 808 can include STT-MRAM memory arrays integrated into a logic processor, as described herein. In an embodiment, the memory device 808 is embedded in the microprocessor 802, as depicted in FIG. 8. In an embodiment, one or more of the above components of electronic system 800 is fabricated using a lithographic mask as described and/or fabricated herein.

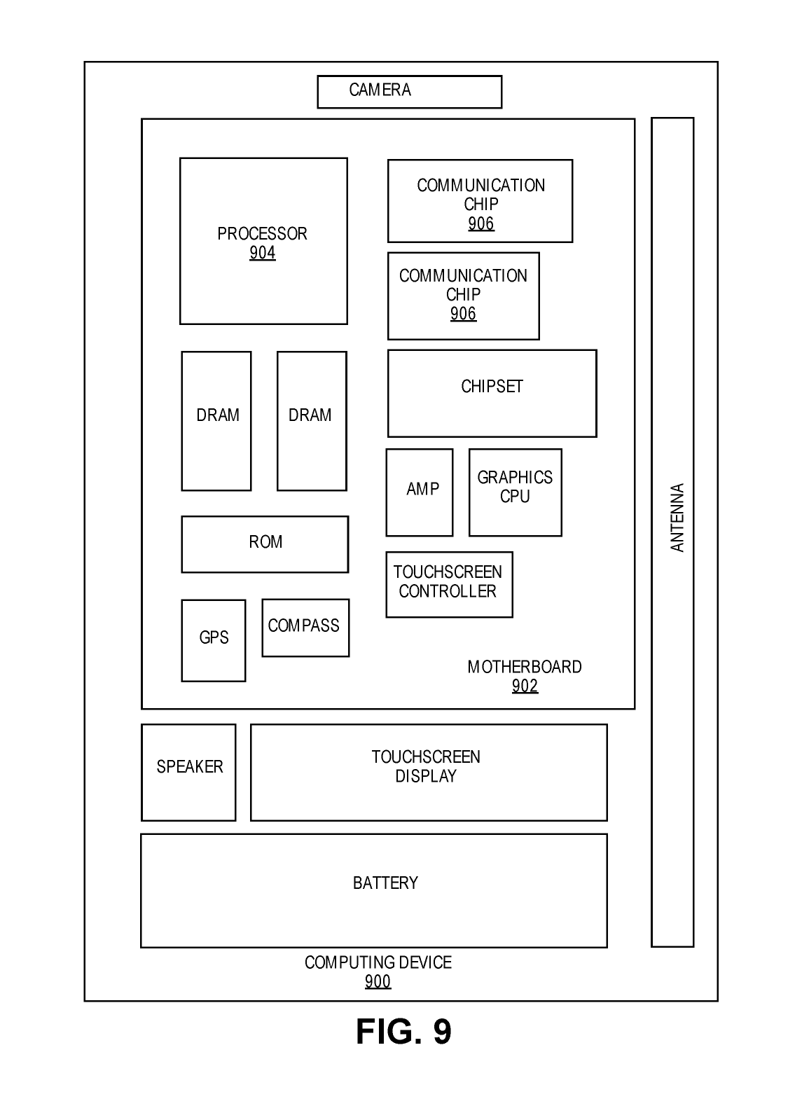

FIG. 9 illustrates a computing device 900 in accordance with one embodiment of the invention. The computing device 900 houses a board 902. The board 902 may include a number of components, including but not limited to a processor 904 and at least one communication chip 906. The processor 904 is physically and electrically coupled to the board 902. In some implementations the at least one communication chip 906 is also physically and electrically coupled to the board 902. In further implementations, the communication chip 906 is part of the processsor 904.

Depending on its applications, computing device 900 may include other components that may or may not be physically and electrically coupled to the board 902. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 906 enables wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 906 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 900 may include a plurality of communication chips 906. For instance, a first communication chip 906 may be dedicated to shorter range wireless communications such as Wi-Fi and Bluetooth and a second communication chip 906 may be dedicated to longer range wireless communications such as GPS, EDGE, GPRS, CDMA, WiMAX, LTE, Ev-DO, and others.

The processor 904 of the computing device 900 includes an integrated circuit die packaged within the processor 904. In some implementations of embodiments of the invention, the integrated circuit die of the processor includes one or more arrays, such a logic processor is fabricated using a lithographic mask as described and/or fabricated herein, in accordance with embodiments of the present invention. The term “processor” may refer to any device or portion of a device that processes electronic data from registers and/or memory to transform that electronic data into other electronic data that may be stored in registers and/or memory.

The communication chip 906 also includes an integrated circuit die packaged within the communication chip 906. In accordance with another implementation of an embodiment of the invention, the integrated circuit die of the communication chip is fabricated using a lithographic mask as described and/or fabricated herein, in accordance with embodiments of the present invention.

In further implementations, another component housed within the computing device 900 may contain a stand-alone integrated circuit memory die that is fabricated using a lithographic mask as described and/or fabricated herein, in accordance with embodiments of the present invention.

In various implementations, the computing device 900 may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device 900 may be any other electronic device that processes data.

Accordingly, one or more embodiments of the present invention relate generally to the fabrication of embedded microelectronic memory. The microelectronic memory may be non-volatile, wherein the memory can retain stored information even when not powered. One or more embodiments of the present invention relate to the fabrication of a logic processor fabricated using a lithographic mask as described and/or fabricated herein, in accordance with embodiments of the present invention.

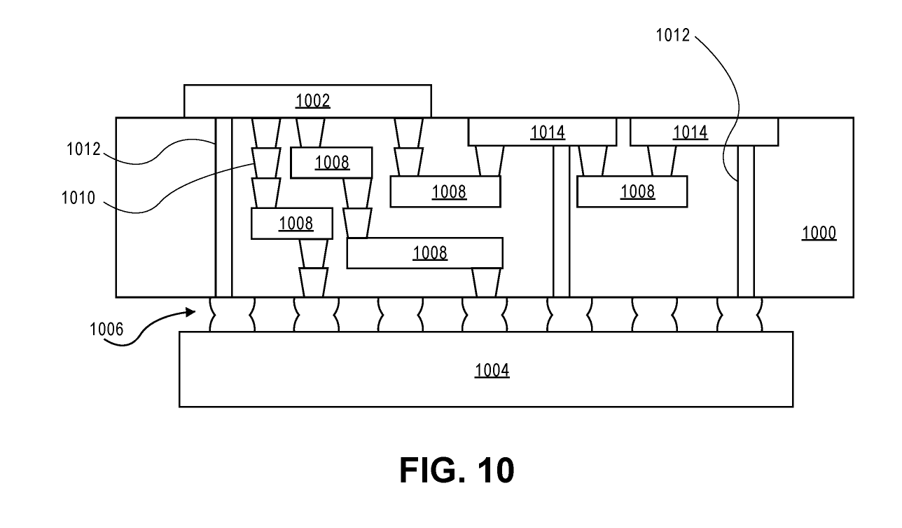

FIG. 10 illustrates an interposer 1000 that includes one or more embodiments of the invention. The interposer 1000 is an intervening substrate used to bridge a first substrate 1002 to a second substrate 1004. The first substrate 1002 may be, for instance, an integrated circuit die. The second substrate 1004 may be, for instance, a memory module, a computer motherboard, or another integrated circuit die. Generally, the purpose of an interposer 1000 is to spread a connection to a wider pitch or to reroute a connection to a different connection. For example, an interposer 1000 may couple an integrated circuit die to a ball grid array (BGA) 1006 that can subsequently be coupled to the second substrate 1004. In some embodiments, the first and second substrates 1002/1004 are attached to opposing sides of the interposer 1000. In other embodiments, the first and second substrates 1002/1004 are attached to the same side of the interposer 1000. And in further embodiments, three or more substrates are interconnected by way of the interposer 1000.

The interposer 1000 may be formed of an epoxy resin, a fiberglass-reinforced epoxy resin, a ceramic material, or a polymer material such as polyimide. In further implementations, the interposer may be formed of alternate rigid or flexible materials that may include the same materials described above for use in a semiconductor substrate, such as silicon, germanium, and other group III-V and group IV materials.

The interposer may include metal interconnects 1008 and vias 1010, including but not limited to through-silicon vias (TSVs) 1012. The interposer 1000 may further include embedded devices 1014, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 1000. In accordance with embodiments of the invention, apparatuses or processes disclosed herein may be used in the fabrication of interposer 1000. In an embodiment, interposer 1000 or portions thereof are fabricated using a lithographic mask as described and/or fabricated herein.

Thus, embodiments described herein include approaches for fabricating a lithographic mask.

In an embodiment, a lithographic mask for patterning semiconductor circuits includes a substrate. An in-die region is disposed on the substrate. The in-die region includes a patterned shifter material in direct contact with the substrate. The patterned shifter material includes features having sidewalls. A frame region is disposed on the substrate and surrounding the in-die region. The frame region includes an absorber layer in direct contact with the substrate.

In one embodiment, the lithographic mask further includes a die-frame interface region disposed on the substrate. The die-frame interface regions includes adjacent portions of the in-die region and the frame region. The die-frame interface region includes an upper layer disposed on a lower layer. The upper layer includes a same material as the absorber layer of the frame region, and the lower layer includes a same material as the patterned shifter material layer of the in-die region.

In one embodiment, the substrate is recessed at locations between the features of the patterned shifter layer.

In one embodiment, the sidewalls of the features of the patterned shifter material have sidewall material thereon, wherein the sidewall material includes a same material as the absorber layer.

In one embodiment, the substrate is quartz.

In one embodiment, the absorber layer is chrome.

In one embodiment, an uppermost surface of the features of the patterned shifter layer has a height different than an uppermost surface of features of the die-frame interface region and different than an uppermost surface of the features in the frame region, and the height of the uppermost surface of the features of the die-frame interface region is different than the height of the uppermost surface of the features of the frame region.

In one embodiment, the shifter layer includes a material selected from the group consisting of MoSi, SiN, SiON, MoSiN, and MoSiON.

In an embodiment, a method of fabricating a photomask includes forming a shifter layer on a substrate. A first patterned resist layer is formed on the shifter layer. A patterned shifter layer is formed by removing regions of the shifter layer exposed by the resist layer, the patterned shifter layer including features having sidewalls. An absorber layer is formed on the patterned shifter layer and on the substrate. The absorber layer is patterned to form a patterned absorber layer having a first portion directly on the substrate and a second portion on a portion of the patterned shifter layer.

In one embodiment, the sidewalls of the features of the shifter layer are sloped.

In one embodiment, patterning the absorber layer includes etching the absorber layer, and the etching leaves sidewall spacers of absorber material adjacent the sidewalls of the features of the patterned shifter layer.

In one embodiment, the method further includes removing the sidewall spacers of the absorber material.

In one embodiment, the method further includes recessing the substrate during the removing of the sidewall spacers of the absorber material.

In one embodiment, forming the shifter layer on the substrate includes forming the shifter layer on a quartz substrate.

In an embodiment, a method of fabricating a photomask includes forming a shifter layer on a substrate. A hardmask layer is formed on the shifter layer. A first patterned resist layer is formed on the hardmask layer. A patterned hardmask layer is formed by removing regions of the hardmask layer exposed by the resist layer. A patterned shifter layer is formed by removing regions of the shifter layer exposed by the hardmask layer. The patterned hardmask layer is removed. Subsequent to removing the hardmask layer, an absorber layer is formed on the patterned shifter layer and on the substrate. The absorber layer is patterned to form a patterned absorber layer having a first portion directly on the substrate and a second portion on a portion of the patterned shifter layer.

In one embodiment, the sidewalls of the features of the shifter layer are sloped.

In one embodiment, removing the absorber layer includes etching the absorber layer, and the etching leaves sidewall spacers of absorber material adjacent sidewalls of features of the shifter layer.

In one embodiment, the method further includes removing the sidewall spacers of absorber material.

In one embodiment, the method further includes recessing the substrate during the removing of the sidewall spacers of the absorber material.

In one embodiment, the substrate is a quartz substrate.

What is claimed is:

1. A lithographic mask for patterning semiconductor circuits, the lithographic mask comprising:
a substrate;
an in-die region disposed on the substrate, the in-die region comprising a patterned shifter material in direct contact with the substrate, wherein the patterned shifter material comprises features having sidewalls; and
a frame region disposed on the substrate and surrounding the in-die region, the frame region comprising an absorber layer in direct contact with the substrate.

2. The lithographic mask of claim 1, further comprising:
a die-frame interface region disposed on the substrate and comprising adjacent portions of the in-die region and the frame region, the die-frame interface region comprising an upper layer disposed on a lower layer, wherein the upper layer comprises a same material as the absorber layer of the frame region, and the lower layer comprises a same material as the patterned shifter material layer of the in-die region.

3. The lithographic mask of claim 1, wherein the substrate is recessed at locations between the features of the patterned shifter layer.

4. The lithographic mask of claim 1, wherein the sidewalls of the features of the patterned shifter material have sidewall material thereon, wherein the sidewall material comprises a same material as the absorber layer.

5. The lithographic mask of claim 1, wherein the substrate is quartz.

6. The lithographic mask of claim 1, where in the absorber layer is chrome.

7. The lithographic mask of claim 2, wherein an uppermost surface of the features of the patterned shifter layer has a height different than an uppermost surface of features of the die-frame interface region and different than an uppermost surface of the features in the frame region, and wherein the height of the uppermost surface of the features of the die-frame interface region is different than the height of the uppermost surface of the features of the frame region.

8. The lithographic mask of claim 1, wherein the shifter layer comprises a material selected from the group consisting of MoSi, SiN, SiON, MoSiN, and MoSiON.

9. A method of fabricating a photomask, the method comprising:
forming a shifter layer on a substrate;
forming a first patterned resist layer on the shifter layer;
forming a patterned shifter layer by removing regions of the shifter layer exposed by the resist layer, the patterned shifter layer comprising features having sidewalls;
forming an absorber layer on the patterned shifter layer and on the substrate; and
patterning the absorber layer to form a patterned absorber layer having a first portion directly on the substrate and a second portion on a portion of the patterned shifter layer.

10. The method of claim 9, wherein the sidewalls of the features of the shifter layer are sloped.

11. The method of claim 9, wherein patterning the absorber layer comprises etching the absorber layer, and wherein the etching leaves sidewall spacers of absorber material adjacent the sidewalls of the features of the patterned shifter layer.

12. The method of claim 11, further comprising removing the sidewall spacers of the absorber material.

13. The method of claim 12, further comprising recessing the substrate during the removing of the sidewall spacers of the absorber material.

14. The method of claim 9, wherein forming the shifter layer on the substrate comprises forming the shifter layer on a quartz substrate.

15. A method of fabricating a photomask, the method comprising:
forming a shifter layer on a substrate;
forming a hardmask layer on the shifter layer;
forming a first patterned resist layer on the hardmask layer;
forming a patterned hardmask layer by removing regions of the hardmask layer exposed by the resist layer;
forming a patterned shifter layer by removing regions of the shifter layer exposed by the hardmask layer;
removing the patterned hardmask layer;
subsequent to removing the hardmask layer, forming an absorber layer on the patterned shifter layer and on the substrate;
patterning the absorber layer to form a patterned absorber layer having a first portion directly on the substrate and a second portion on a portion of the patterned shifter layer.

16. The method of claim 15, wherein the sidewalls of the features of the shifter layer are sloped.

17. The method of claim 15, wherein removing the absorber layer comprises etching the absorber layer, and wherein the etching leaves sidewall spacers of absorber material adjacent sidewalls of features of the shifter layer.

18. The method of claim 17, further comprising removing the sidewall spacers of absorber material.

19. The method of claim 18, further comprising recessing the substrate during the removing of the sidewall spacers of the absorber material.

20. The method of claim 15, wherein forming the shifter layer on the substrate comprises forming the shifter layer on a quartz substrate.
